(19) United States
(12) Patent Application Publication
(10) Pub. No.: US 2024/0425969 A1
(43) Pub. Date: Dec. 26, 2024

(54) DEPOSITION SOURCE

(71) Applicant: Samsung Display Co., LTD., Yongin-si (KR)

(72) Inventors: In Ae HAN, Yongin-si (KR); Jong Bun HAN, Yongin-si (KR); Gan Young PARK, Yongin-si (KR)

(73) Assignee: Samsung Display Co., LTD., Yongin-si (KR)

(21) Appl. No.: 18/414,701

(22) Filed: Jan. 17, 2024

(30) Foreign Application Priority Data
Jun. 21, 2023 (KR) 10-2023-0079903

(51) Int. Cl. C23C 14/24

(52) U.S. Cl. CPC C23C 14/243

(57) ABSTRACT

A deposition source includes a first frame including a lower space of a first crucible, a lower space of a second crucible, and a first partition wall disposed between the lower space of the first crucible and the lower space of the second crucible; and a second frame including an upper space of the first crucible, an upper space of the second crucible, a first nozzle connected to the first crucible, a second nozzle connected to the second crucible, and a second partition wall disposed between the upper space of the first crucible and the upper space of the second crucible, wherein an exhaust passage is disposed between the first partition wall of the first frame and the second partition wall of the second frame, and the first partition wall contacts the second partition wall.

### CROSS-REFERENCE TO RELATED APPLICATION(S)

The application claims priority to and benefits of Korean Patent Application No. 10-2023-0079903 under 35 U.S.C. § 119, filed Jun. 21, 2023, in the Korean Intellectual Property Office, the entire contents of which are incorporated herein by reference.

### BACKGROUND

### 1. Technical Field

Embodiments relate to a deposition source.

### 2. Description of the Related Art

As information technology develops, the importance of a display device as a connection medium between a user and information is being emphasized. Thus, the usage of display devices such as a liquid crystal display device and an organic light emitting display device is increasing.

Electrodes, a light emitting layer, an organic layer, an inorganic layer, and the like in a display device may be formed by various methods. A representative method may be a vacuum deposition method in which a predetermined material is deposited in a vacuum atmosphere to form a thin film. The vacuum deposition method may be performed by disposing a mask between a deposition source and a target substrate in a chamber, sublimating or vaporizing a deposition material of the deposition source, and depositing the deposition material on the target substrate.

### SUMMARY

Embodiments provide a deposition source capable of preventing deposition materials from being mixed inside.

However, embodiments of the disclosure are not limited to those set forth herein. The above and other embodiments will become more apparent to one of ordinary skill in the art to which the disclosure pertains by referencing the detailed description of the disclosure given below.

A deposition source according to an embodiment may include a first frame including a lower space of a first crucible, a lower space of a second crucible, and a first partition wall disposed between the lower space of the first crucible and the lower space of the second crucible; and a second frame including an upper space of the first crucible, an upper space of the second crucible, a first nozzle connected to the first crucible, a second nozzle connected to the second crucible, and a second partition wall disposed between the upper space of the first crucible and the upper space of the second crucible. An exhaust passage may be disposed between a first partition wall of the first frame and a second partition wall of the second frame. The first partition wall of the first frame may contact the second partition wall of the second frame.

The first nozzle and the second nozzle may be arranged in a first direction.

The exhaust passage may extend in the first direction.

The first crucible and the second crucible may be arranged in a second direction intersecting the first direction.

Each of the first crucible and the second crucible may extend in the first direction.

The deposition source may further include a fastening member penetrating the exhaust passage and fastening the first partition wall and the second partition wall.

The fastening member may be a bolt.

A lower portion of the exhaust passage may be formed as a portion of the first partition wall, and an upper portion of the exhaust passage may be formed as a portion of the second partition wall.

The upper portion of the exhaust passage may be formed as a trench of the second partition wall, and the lower portion of the exhaust passage may be formed as a flat surface of the first partition wall.

The upper portion of the exhaust passage may be formed as a flat surface of the second partition wall, and the lower portion of the exhaust passage may be formed as a trench of the first partition wall.

The upper portion of the exhaust passage may be formed as a trench of the second partition wall, and the lower portion of the exhaust passage may be formed as a trench of the first partition wall.

A deposition source according to another embodiment may include a (1-1)th frame including a lower space of a first crucible; a (1-2)th frame including a lower space of a second crucible; and a second frame including an upper space of the first crucible, an upper space of the second crucible, a first nozzle connected to the first crucible, and a second nozzle connected to the second crucible. A first portion of a partition wall of the second frame disposed between the first crucible and the second crucible may contact the (1-1)th frame, and a second portion of the partition wall may contact the (1-2)th frame.

A portion of the (1-1)th frame in contact with the first portion of the partition wall of the second frame may be spaced apart from a portion of the (1-2)th frame in contact with the second portion of the partition wall of the second frame.

The first nozzle and the second nozzle may be arranged in a first direction.

The first crucible and the second crucible may be arranged in a second direction intersecting the first direction.

Each of the first crucible and the second crucible may extend in the first direction.

A deposition source according to another embodiment may include a first frame including a lower space of a first crucible and a lower space of a second crucible; a (2-1)th frame including an upper space of the first crucible and a first nozzle connected to the first crucible; and a (2-2)th frame including an upper space of the second crucible and a second nozzle connected to the second crucible. A first portion of a partition wall of the first frame disposed between the first crucible and the second crucible may contact the (2-1)th frame, and a second portion of the partition wall of the first frame may contact the (2-2)th frame.

A portion of the (2-1)th frame in contact with the first portion of the partition wall of the first frame may be spaced apart from a portion of the (2-2)th frame in contact with the second portion of the partition wall of the first frame.

The first nozzle and the second nozzle may be arranged in a first direction.

The first crucible and the second crucible may be arranged in a second direction intersecting the first direction.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and, together with the description, serve to explain principles of the inventive concepts.

FIGS. 1 and 2 are schematic diagrams for describing a deposition apparatus according to an embodiment.

FIGS. 3 and 4 are schematic diagrams for describing a deposition source according to a first embodiment.

FIGS. 5, 6, 7, 8, 9, 10, and 11 are schematic diagrams for describing deposition sources according to a second embodiment.

FIGS. 12 and 13 are schematic diagrams for describing a deposition source according to a third embodiment.

FIGS. 14 and 15 are schematic diagrams for describing a deposition source according to a fourth embodiment.

### DETAILED DESCRIPTION OF THE ILLUSTRATED EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

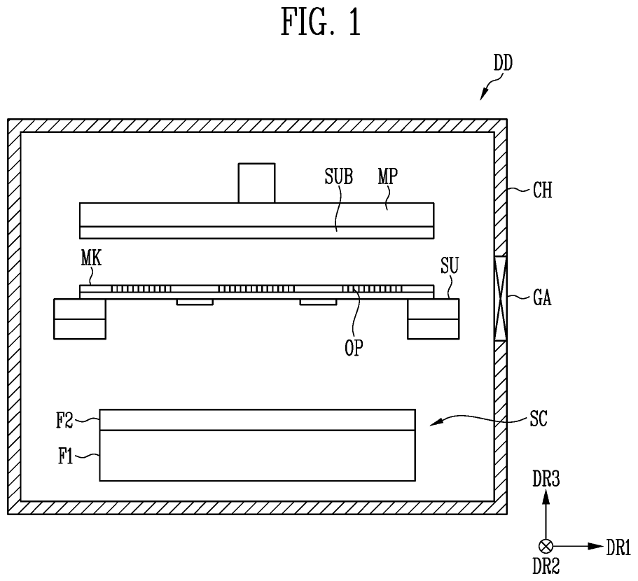

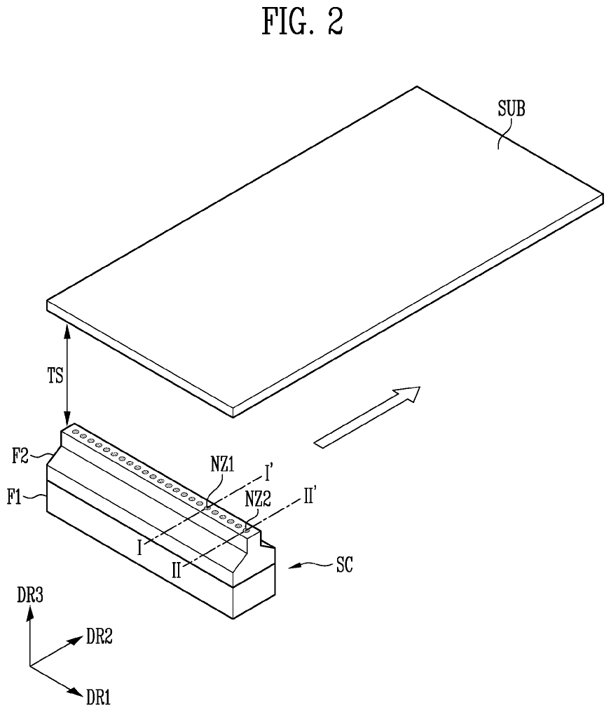

FIGS. 1 and 2 are schematic diagrams for describing a deposition apparatus according to an embodiment.

Referring to FIG. 1, a deposition apparatus DD according to an embodiment may include a chamber CH, a moving plate MP, a mask assembly MK, and a deposition source SC.

The deposition apparatus DD may deposit a deposition material on a target substrate SUB. For example, the target substrate SUB may be a substrate of a display device. The deposition material may include an organic material, an inorganic material, or the like. For example, the deposition material may be deposited on the target substrate SUB to form an organic light emitting element.

The chamber CH may have an enclosed space therein. The moving plate MP, the mask assembly MK, and the deposition source SC may be disposed in an inner space of the chamber CH. The chamber CH may have one or more gates GA. For example, the gate GA may be disposed on a sidewall of the chamber CH. The gate GA may open and close the inner space of the chamber CH. For example, the target substrate SUB may enter or exit the inner space of the chamber CH through the gate GA.

The moving plate MP may be movable inside the chamber CH. For example, the moving plate MP may move in a first direction DR1, a second direction DR2, or a third direction DR3 in case that an upper portion of the moving plate MP is connected to a ceiling of the chamber CH.

The first direction DR1, the second direction DR2, and the third direction DR3 may be directions perpendicular to each other. Hereinafter, the first direction DR1 and the second direction DR2 may indicate a horizontal direction, and the third direction DR3 may indicate a vertical direction.

The target substrate SUB may be disposed under the moving plate MP. The moving plate MP may grip the target substrate SUB by using electrostatic force or magnetic force. The moving plate MP may move the target substrate SUB inside the chamber CH.

The mask assembly MK may be disposed between the target substrate SUB and the deposition source SC. The mask assembly MK may overlap the target substrate SUB. The mask assembly MK may be supported by a supporter SU disposed inside the chamber CH.

Openings OP may be defined in the mask assembly MK. Deposition materials sprayed from the deposition source SC may pass through the openings OP and be deposited on the target substrate SUB.

The deposition source SC may be disposed under the mask assembly MK. The deposition source SC may accommodate the deposition material. The deposition source SC may accommodate a single deposition material or deposition materials.

The deposition source SC may vaporize or sublimate the deposition material accommodated therein and provide it to the target substrate SUB.

FIG. 2 is a schematic diagram showing a method in which the deposition source SC shown in FIG. 1 moves, as an example. For convenience of description, in FIG. 2, the target substrate SUB and the deposition source SC shown in FIG. 1 are shown, and other components are omitted.

Referring to FIG. 2, the target substrate SUB may be disposed in the third direction DR3 from the deposition source SC. A surface of the target substrate SUB may face the deposition source SC, and may be spaced apart from the deposition source SC by a distance TS. A side of the target substrate SUB may extend in the first direction DR1 and another side may extend in the second direction DR2.

For example, the deposition source SC may be a linear deposition source. For example, the deposition source SC may include nozzles NZ1 and NZ2 arranged in the first direction DR1.

In case that the deposition source SC accommodates only a single deposition material, the nozzles NZ1 and NZ2 may be connected to a crucible storing the single deposition material.

In case that the deposition source SC accommodates a first deposition material and a second deposition material that are different from each other, first nozzles NZ1 may be connected to a first crucible storing the first deposition material, and second nozzles NZ2 may be connected to a second crucible storing the second deposition material. The first nozzles NZ1 and the second nozzles NZ2 may be arranged in the first direction DR1. For example, the first nozzles NZ1 and the second nozzles NZ2 may be alternately disposed in the first direction DR1.

In another example, the deposition source SC accommodates a first deposition material, a second deposition material, and a third deposition material that are different from each other, third nozzles may be further provided. For example, the first nozzles NZ1 may be connected to a first crucible storing the first deposition material, the second nozzles NZ2 may be connected to a second crucible storing the second deposition material, and the third nozzles may be connected to a third crucible storing the third deposition material. The first nozzles NZ1, the second nozzles NZ2, and the third nozzles may be alternately disposed in the first direction DR1.

As such, the number of deposition materials may be applied to the deposition source SC according to embodiments. However, embodiments are not limited. Hereinafter, for convenience of description, a case in which the deposition source SC includes the first deposition material and the second deposition material will be described as an example.

The deposition source SC may include a first frame F1 and a second frame F2. The second frame F2 may be a frame including nozzles NZ1 and NZ2. The second frame F2 may be positioned in the third direction DR3 from the first frame F1.

The deposition source SC may spray deposition materials with moving in the second direction DR2. Accordingly, a thin film may be formed on an entire surface of the target substrate SUB.

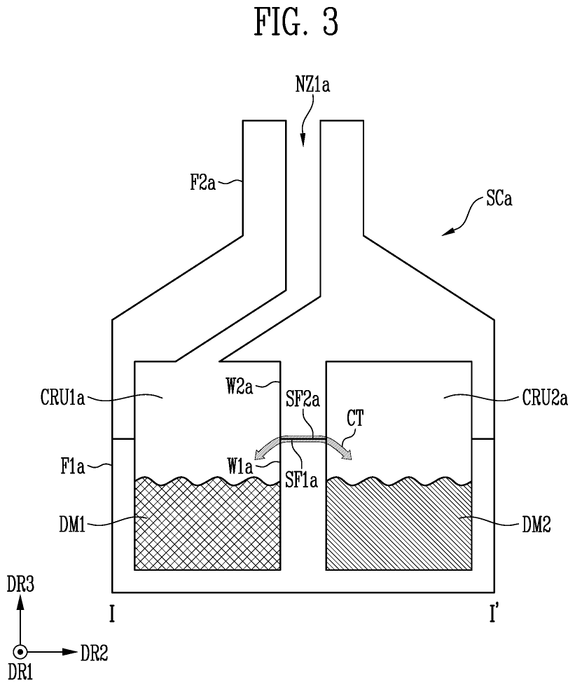

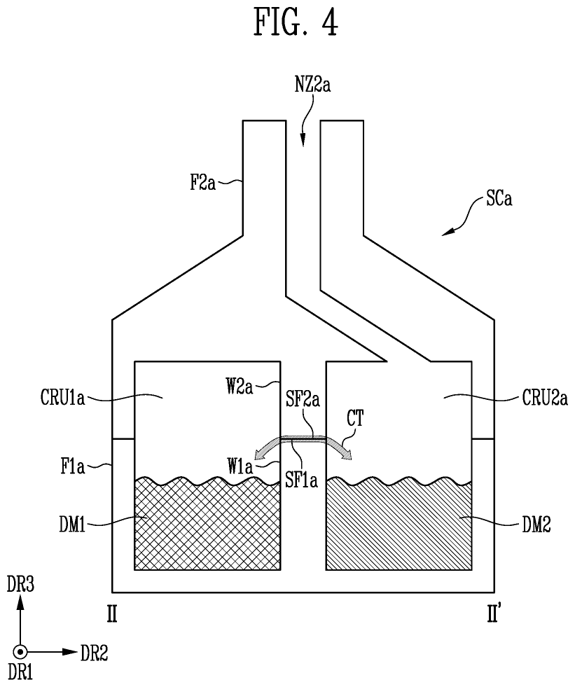

FIGS. 3 and 4 are schematic diagrams for describing a deposition source according to a first embodiment. FIG. 3 is an example of a schematic cross-sectional view of a deposition source SCa taken along line I-I′ of FIG. 2. FIG. 4 is an example of a schematic cross-sectional view of the deposition source SCa taken along line II-II′ of FIG. 2.

The deposition source SCa may include a first frame F1a and a second frame F2a.

The first frame F1a may include a lower space of a first crucible CRU1a and a lower space of a second crucible CRU2a. The first frame F1a may be integrally formed to be a single body.

The second frame F2a may include an upper space of the first crucible CRU1a, an upper space of the second crucible CRU2a, a first nozzle NZ1a connected to the first crucible CRU1a, and a second nozzle NZ2a connected to the second crucible CRU2a. The second frame F2a may be integrally formed to be a single body.

The first crucible CRU1a may refer to a space in which the lower space and the upper space are combined with each other. The first crucible CRU1a may accommodate the first deposition material DM1.

The second crucible CRU2a may refer to a space in which the lower space and the upper space are combined with each other. The second crucible CRU2a may accommodate the second deposition material DM2.

The first crucible CRU1a and the second crucible CRU2a may be arranged in the second direction DR2. Each of the first crucible CRU1a and the second crucible CRU2a may extend in the first direction DR1.

The first frame F1a may include a first partition wall W1a positioned between the first crucible CRU1a and the second crucible CRU2a. The first partition wall W1a may separate the lower space of the first crucible CRU1a and the lower space of the second crucible CRU2a.

The second frame F2a may include a second partition wall W2a positioned between the first crucible CRU1a and the second crucible CRU2a. The second partition wall W2a may separate the upper space of the first crucible CRU1a and the upper space of the second crucible CRU2a.

A surface SF1a of the first partition wall W1a and a surface SF2a of the second partition wall W2a may be in contact with each other to prevent mixing of the first deposition material DM1 and the second deposition material DM2.

However, the deposition materials DM1 and DM2 may form a mixture flowing CT in the first crucible CRU1a or the second crucible CRU2a along a gap between the first partition wall W1a and the second partition wall W2a. In case that the mixture flowing CT is formed/occurred, an error may occur in sensing the amount of deposition, and a problem in that the amount of deposition is not smoothly controlled may occur.

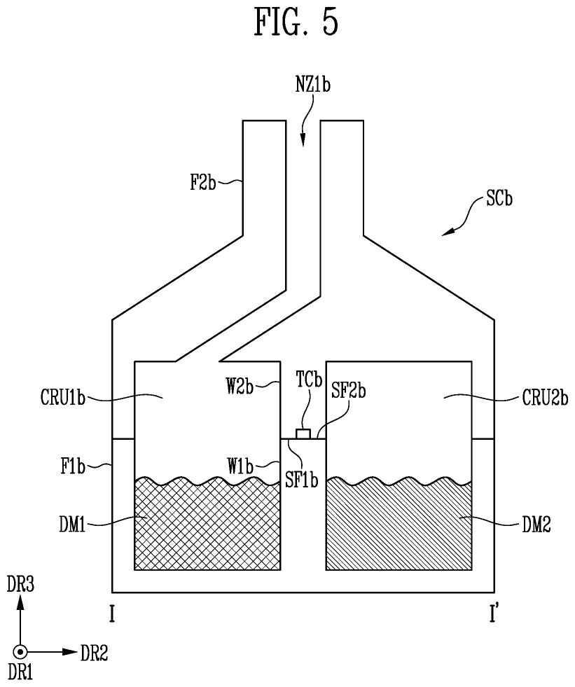

FIGS. 5, 6, 7, 8, 9, 10, and 11 are schematic diagrams for describing deposition sources according to a second embodiment.

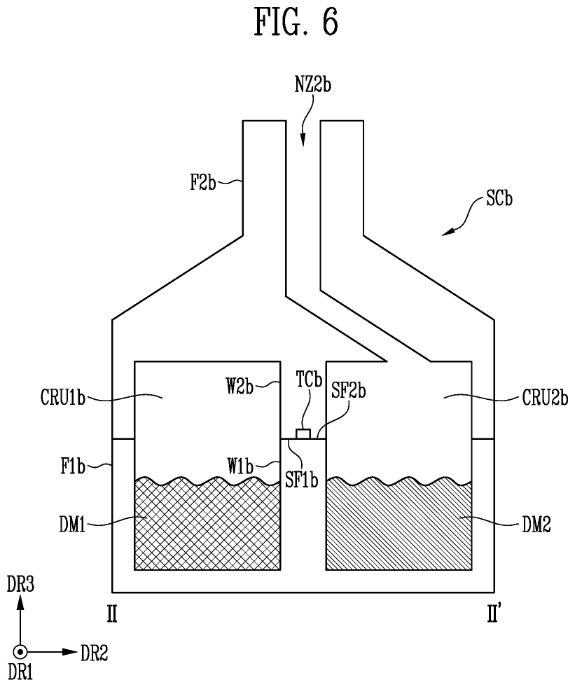

FIG. 5 is an example of a schematic cross-sectional view of a deposition source SCb taken along line I-I′ of FIG. 2. FIG. 6 is an example of a schematic cross-sectional view of the deposition source SCb taken along line II-II′ of FIG. 2.

The deposition source SCb may include a first frame Fib and a second frame F2b.

The first frame Fib may include a lower space of a first crucible CRU1b and a lower space of a second crucible CRU2b. The first frame Fib may be integrally formed to be a single body.

The second frame F2b may include an upper space of the first crucible CRU1b, an upper space of the second crucible CRU2b, a first nozzle NZ1b connected to the first crucible CRU1b, and a second nozzle NZ2b connected to the second crucible CRU2b. The second frame F2b may be integrally formed to be a single body.

The first crucible CRU1b may refer to a space in which the lower space and the upper space are combined with each other. The first crucible CRU1b may accommodate the first deposition material DM1.

The second crucible CRU2b may refer to a space in which the lower space and the upper space are combined with each other. The second crucible CRU2b may accommodate the second deposition material DM2.

The first crucible CRU1b and the second crucible CRU2b may be arranged in the second direction DR2. Each of the first crucible CRU1b and the second crucible CRU2b may extend in the first direction DR1.

The first frame Fib may include a first partition wall W1b positioned between the first crucible CRU1b and the second crucible CRU2b. The first partition wall W1b may separate the lower space of the first crucible CRU1b and the lower space of the second crucible CRU2b.

The second frame F2b may include a second partition wall W2b positioned between the first crucible CRU1b and the second crucible CRU2b. The second partition wall W2b may separate the upper space of the first crucible CRU1b and the upper space of the second crucible CRU2b.

A surface SF1b of the first partition wall W1b and a surface SF2b of the second partition wall W2b may be in contact with each other to prevent mixing of the first deposition material DM1 and the second deposition material DM2.

According to an embodiment, an exhaust passage VH may be positioned between the first partition wall W1b of the first frame Fib and the second partition wall W2b of the second frame F2b positioned between the first crucible CRU1b and the second crucible CRU2b.

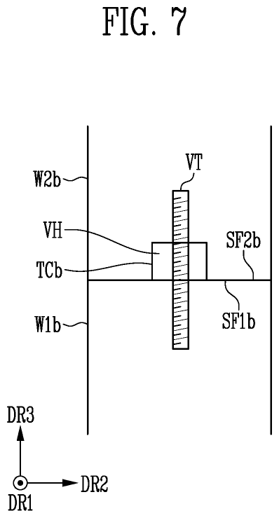

Referring to FIG. 7, an area around an exhaust passage VH is shown enlarged.

A lower portion of the exhaust passage VH may be formed as a portion of the first partition wall W1b, and an upper portion of the exhaust passage VH may be formed as a portion of the second partition wall W2b. For example, the upper portion of the exhaust passage VH may be formed as a trench TCb of the second partition wall W2b, and the lower portion of the exhaust passage VH may be formed as a flat surface SF1b of the first partition wall W1b. The exhaust passage VH may extend in the first direction DR1.

According to the embodiment, unlike FIGS. 3 and 4, in case that the deposition material flows into a gap between the first partition wall W1b and the second partition wall W2b, the deposition material may be discharged to the outside of the deposition source SCb through the exhaust passage VH. Accordingly, mixing of the deposition materials DM1 and DM2 in the first crucible CRU1b or the second crucible CRU2b may be prevented.

According to an embodiment, the deposition source SCb may further include a fastening member VT that penetrates the exhaust passage VH and fastens the first partition wall W1b and the second partition wall W2b. For example, the fastening member VT may be a bolt.

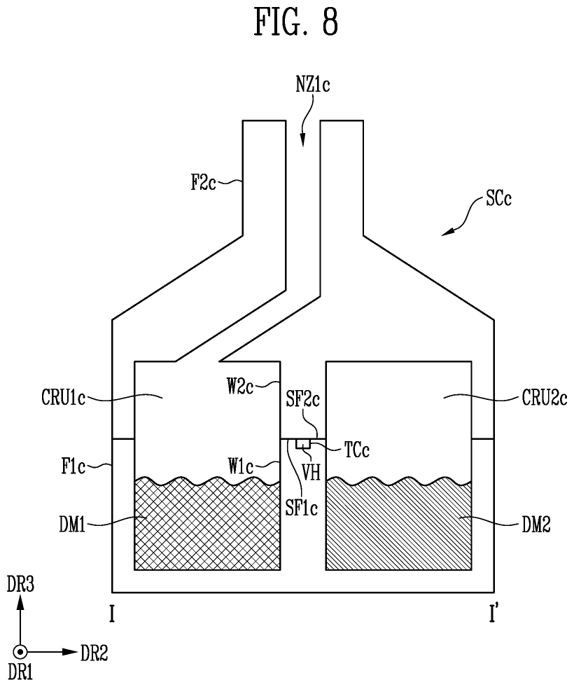

Since the fastening member VT tightens the upper and lower portions of the exhaust passage VH, the possibility that the deposition material flows out of the exhaust passage VH may be further reduced. The embodiment of the fastening member VT may be applied to all of exhaust passages VH of FIGS. 8, 9, 10, and 11 below, and redundant description thereof will be omitted for descriptive convenience.

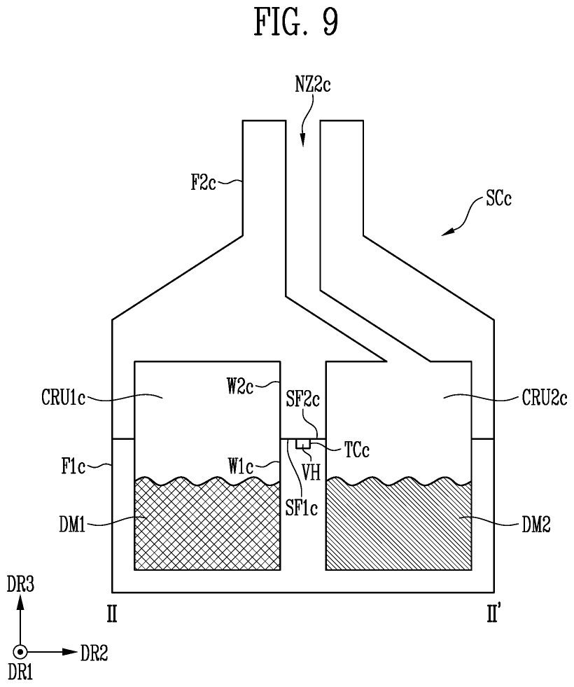

FIG. 8 is an example of a schematic cross-sectional view of a deposition source SCc taken along line I-I′ of FIG. 2. FIG. 9 is an example of a schematic cross-sectional view of the deposition source SCc taken along line II-II′ of FIG. 2.

The deposition source SCc may include a first frame F1c and a second frame F2c.

The first frame F1c may include a lower space of a first crucible CRU1c and a lower space of a second crucible CRU2c. The first frame F1c may be integrally formed to be a single body.

The second frame F2c may include an upper space of the first crucible CRU1c, an upper space of the second crucible CRU2c, a first nozzle NZ1c connected to the first crucible CRU1c, and a second nozzle NZ2c connected to the second crucible CRU2c. The second frame F2c may be integrally formed to be a single body.

The first crucible CRU1c may be referred to as a space in which the lower space and the upper space are combined with each other. The first crucible CRU1c may accommodate the first deposition material DM1.

The second crucible CRU2c may refer to a space in which the lower space and the upper space are combined with each other. The second crucible CRU2c may accommodate the second deposition material DM2.

The first crucible CRU1c and the second crucible CRU2c may be arranged in the second direction DR2. Each of the first crucible CRU1c and the second crucible CRU2c may extend in the first direction DR1.

The first frame F1c may include a first partition wall W1c positioned between the first crucible CRU1c and the second crucible CRU2c. The first partition wall W1c may separate the lower space of the first crucible CRU1c and the lower space of the second crucible CRU2c.

The second frame F2c may include a second partition wall W2c positioned between the first crucible CRU1c and the second crucible CRU2c. The second partition wall W2c may separate the upper space of the first crucible CRU1c and the upper space of the second crucible CRU2c.

A surface SF1c of the first partition wall W1c and a surface SF2c of the second partition wall W2c may be in contact each other to prevent mixing of the first deposition material DM1 and the second deposition material DM2.

According to an embodiment, an exhaust passage VH may be positioned between the first partition wall W1c of the first frame F1c and the second partition wall W2c of the second frame F2c positioned between the first crucible CRU1c and the second crucible CRU2c.

A lower portion of the exhaust passage VH may be formed as a portion of the first partition wall W1c, and an upper portion of the exhaust passage VH may be formed as a portion of the second partition wall W2c. For example, the upper portion of the exhaust passage VH may be formed as a flat surface SF2c of the second partition wall W2c, and the lower portion of the exhaust passage VH may be formed as a trench TCc of the first partition wall W1c. The exhaust passage VH may extend in the first direction DR1.

According to the embodiment, unlike FIGS. 3 and 4, in case that the deposition material flows into a gap between the first partition wall W1c and the second partition wall W2c, the deposition material may be discharged to the outside of the deposition source SCc through the exhaust passage VH. Accordingly, mixing of the deposition materials DM1 and DM2 in the first crucible CRU1c or the second crucible CRU2c may be prevented.

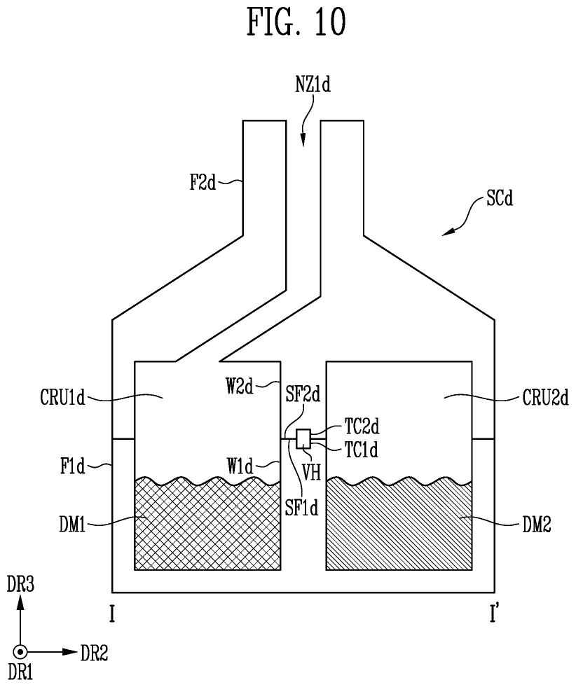

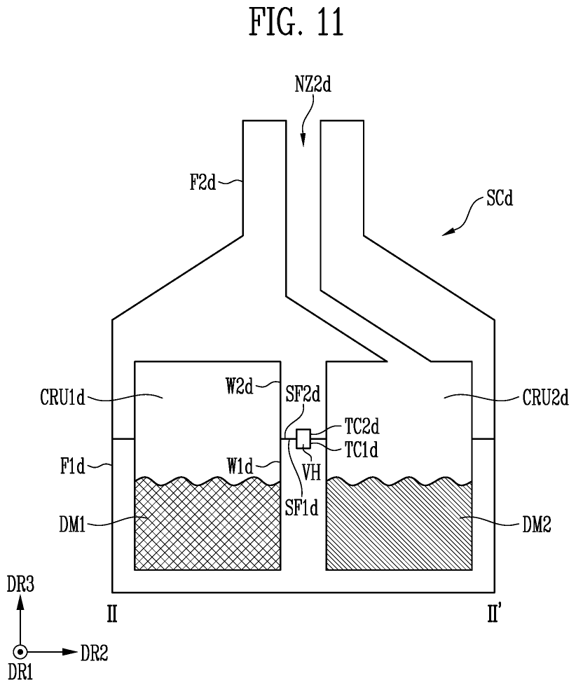

FIG. 10 is an example of a schematic cross-sectional view of a deposition source SCd taken along line I-I′ of FIG. 2. FIG. 11 is an example of a schematic cross-sectional view of the deposition source SCd taken along line II-II′ of FIG. 2.

The deposition source SCd may include a first frame F1d and a second frame F2d.

The first frame F1d may include a lower space of a first crucible CRU1d and a lower space of a second crucible CRU2d. The first frame F1d may be integrally formed to be a single body.

The second frame F2d may include an upper space of the first crucible CRU1d, an upper space of the second crucible CRU2d, a first nozzle NZ1d connected to the first crucible CRU1d, and a second nozzle NZ2d connected to the second crucible CRU2d. The second frame F2d may be integrally formed to be a single body.

The first crucible CRU1d may refer to a space in which the lower space and the upper space are combined with each other. The first crucible CRU1d may accommodate the first deposition material DM1.

The second crucible CRU2d may refer to a space in which the lower space and the upper space are combined with each other. The second crucible CRU2d may accommodate the second deposition material DM2.

The first crucible CRU1d and the second crucible CRU2d may be arranged in the second direction DR2. Each of the first crucible CRU1d and the second crucible CRU2d may extend in the first direction DR1.

The first frame F1d may include a first partition wall W1d positioned between the first crucible CRU1d and the second crucible CRU2d. The first partition wall W1d may separate the lower space of the first crucible CRU1d and the lower space of the second crucible CRU2d.

The second frame F2d may include a second partition wall W2d positioned between the first crucible CRU1d and the second crucible CRU2d. The second partition wall W2d may separate the upper space of the first crucible CRU1d and the upper space of the second crucible CRU2d.

A surface SF1d of the first partition wall W1d and a surface SF2d of the second partition wall W2d may be in contact with each other to prevent mixing of the first deposition material DM1 and the second deposition material DM2.

According to an embodiment, an exhaust passage VH may be positioned between the first partition wall W1d of the first frame F1d and the second partition wall W2d of the second frame F2d positioned between the first crucible CRU1d and the second crucible CRU2d.

A lower portion of the exhaust passage VH may be formed as a portion of the first partition wall W1d, and an upper portion of the exhaust passage VH may be formed as a portion of the second partition wall W2d. For example, the upper portion of the exhaust passage VH may be formed as a trench TC2d of the second partition wall W2d, and the lower portion of the exhaust passage VH may be formed as a trench TC1d of the first partition wall W1d. The exhaust passage VH may extend in the first direction DR1.

According to the embodiment, unlike FIGS. 3 and 4, in case that the deposition material flows into a gap between the first partition wall W1d and the second partition wall W2d, the deposition material may be discharged to the outside of the deposition source SCd through the exhaust passage VH. Accordingly, mixing of the deposition materials DM1 and DM2 in the first crucible CRU1d or the second crucible CRU2d may be prevented.

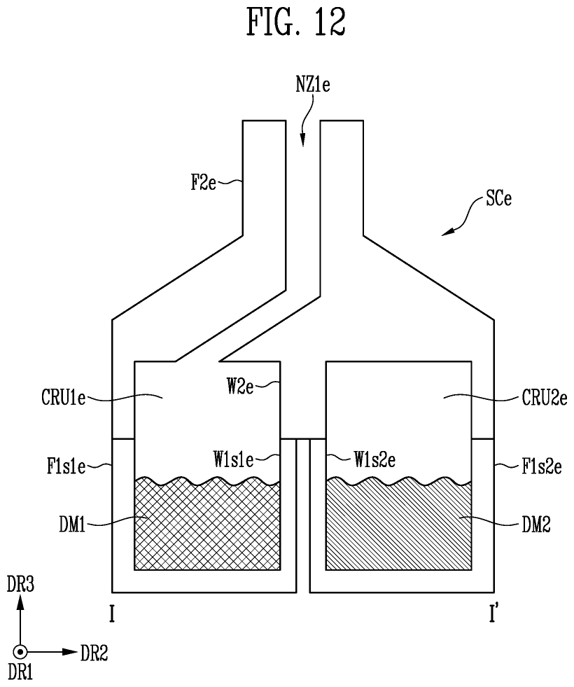

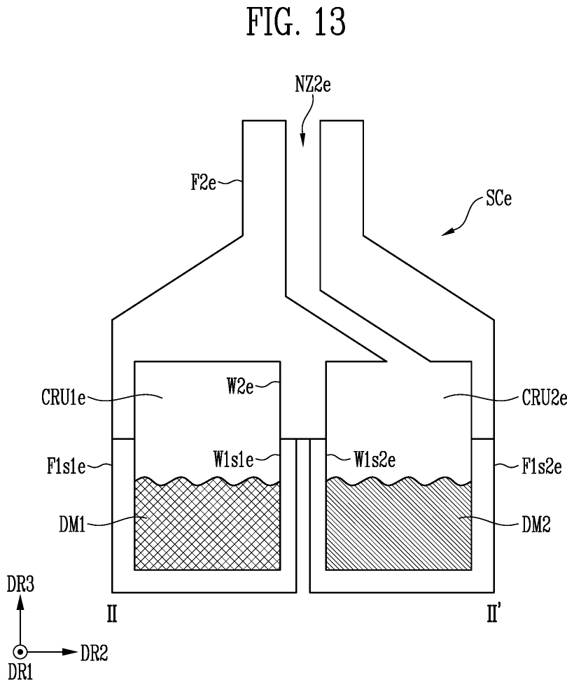

FIGS. 12 and 13 are schematic diagrams for describing a deposition source according to a third embodiment.

FIG. 12 is an example of a schematic cross-sectional view of a deposition source SCe taken along line I-I′ of FIG. 2. FIG. 13 is an example of a schematic cross-sectional view of the deposition source SCe taken along line II-II′ of FIG. 2.

The deposition source SCe may include a (1-1)th frame F1s1e, a (1-2)th frame F1s2e, and a second frame F2e.

The (1-1)th frame F1s1e may include a lower space of a first crucible CRU1e.

The (1-2)th frame F1s2e may include a lower space of a second crucible CRU2e.

The second frame F2e may include an upper space of the first crucible CRU1e, an upper space of the second crucible CRU2e, a first nozzle NZ1e connected to the first crucible CRU1e, and a second nozzle NZ2e connected to the second crucible CRU2e. The second frame F2e may be integrally formed to be a single body.

The first crucible CRU1e may refer to a space in which the lower space and the upper space are combined with each other. The first crucible CRU1e may accommodate the first deposition material DM1.

The second crucible CRU2e may refer to a space in which the lower space and the upper space are combined with each other. The second crucible CRU2e may accommodate the second deposition material DM2.

The first crucible CRU1e and the second crucible CRU2e may be arranged in the second direction DR2. Each of the first crucible CRU1e and the second crucible CRU2e may extend in the first direction DR1.

The second frame F2e may include a partition wall W2e positioned between the first crucible CRU1e and the second crucible CRU2e. The partition wall W2e may separate the upper space of the first crucible CRU1e and the upper space of the second crucible CRU2e.

A portion of the partition wall W2e of the second frame F2e positioned between the first crucible CRU1e and the second crucible CRU2e may contact the (1-1)th frame F1s1e, and another portion of the partition wall W2e may contact the (1-2)th frame F1s2e. For example, a portion of the partition wall W2e may contact the partition wall W1s1e of the (1-1)th frame F1s1e, and another portion of the partition wall W2e may contact the partition wall W1s2e of the (1-2)th frame F1s2e.

The partition wall W1s1e of the (1-1)th frame F1s1e in contact with the portion of the partition wall W2e may be spaced apart from the partition wall W1s2e of the (1-2)th frame F1s2e in contact with another portion of the partition wall W2e. Accordingly, in the embodiment of FIGS. 12 and 13, even though an exhaust passage is not provided, undesirable deposition materials may be discharged through spaces between the partition walls W2e, W1s1e, and W1s2e. Accordingly, mixing of the deposition materials DM1 and DM2 in the first crucible CRU1e or the second crucible CRU2e may be prevented.

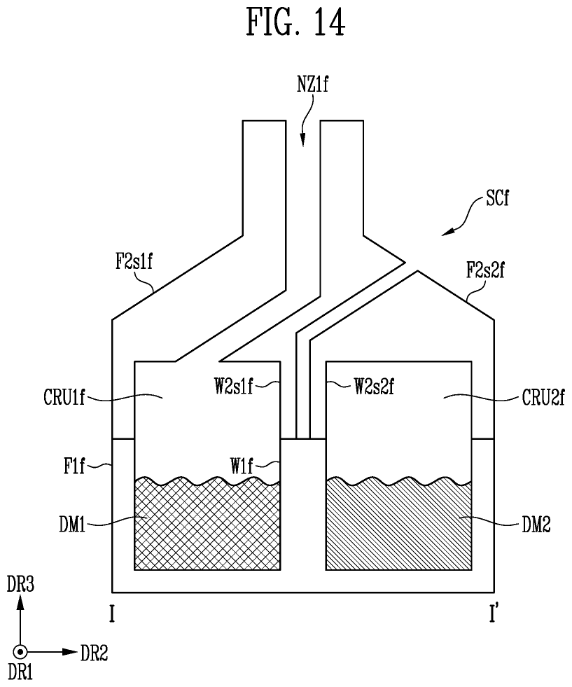

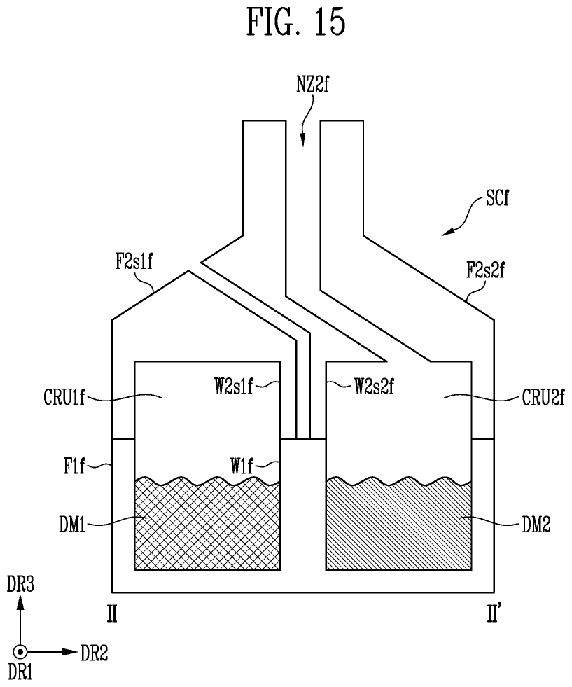

FIGS. 14 and 15 are schematic diagrams for describing a deposition source according to a fourth embodiment.

FIG. 14 is an example of a schematic cross-sectional view of a deposition source SCf taken along line I-I′ of FIG. 2. FIG. 15 is an example of a schematic cross-sectional view of the deposition source SCf taken along line II-II′ of FIG. 2.

The deposition source SCf may include a first frame F1f, a (2-1)th frame F2s1f, and a (2-2)th frame F2s2f.

The first frame F1f may include a lower space of a first crucible CRU1f and a lower space of a second crucible CRU2f. The first frame F1f may be integrally formed to be a single body.

The (2-1)th frame F2s1f may include an upper space of the first crucible CRU1f and a first nozzle NZ1f connected to the first crucible CRU1f.

The (2-2)th frame F2s2f may include an upper space of the second crucible CRU2f and a second nozzle NZ2f connected to the second crucible CRU2f.

The first crucible CRU1f may refer to a space in which the lower space and the upper space are combined with each other. The first crucible CRU1f may accommodate the first deposition material DM1.

The second crucible CRU2f may refer to a space in which the lower space and the upper space are combined with each other. The second crucible CRU2f may accommodate the second deposition material DM2.

The first crucible CRU1f and the second crucible CRU2f may be arranged in the second direction DR2. Each of the first crucible CRU1f and the second crucible CRU2f may extend in the first direction DR1.

The first frame F1f may include a partition wall W1f positioned between the first crucible CRU1f and the second crucible CRU2f The partition wall W1f may separate the lower space of the first crucible CRU1f and the lower space of the second crucible CRU2f.

A portion of the partition wall W1f of the first frame F1f positioned between the first crucible CRU1f and the second crucible CRU2f may contact the (2-1)th frame F2s1f, and another portion of the partition wall W1f may contact the (2-2)th frame F2s2f. For example, a portion of the partition wall W1f may contact the partition wall W2s1f of the (2-1)th frame F2s1f, and another portion of the partition wall W1f may contact the partition wall W2s2f of the (2-2)th frame F2s2f.

The partition wall W2s1f of the (2-1)th frame F2s1f in contact with the portion of the partition wall W1f may be spaced apart from the partition wall W2s2f of the (2-2)th frame F2s2f in contact with another portion of the partition wall W1f. Accordingly, in the embodiment of FIGS. 14 and 15, even though an exhaust passage is not provided, undesirable deposition materials may be discharged through spaces between the partition walls W1f, W2s1f, and W2s2f. Accordingly, mixing of the deposition materials DM1 and DM2 in the first crucible CRU1f or the second crucible CRU2f may be prevented.

The deposition source according to the invention may prevent deposition materials from being mixed inside.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A deposition source comprising:
a first frame including:
a lower space of a first crucible,
a lower space of a second crucible, and
a first partition wall disposed between the lower space of the first crucible and the lower space of the second crucible; and
a second frame including:
an upper space of the first crucible,
an upper space of the second crucible,
a first nozzle connected to the first crucible,
a second nozzle connected to the second crucible, and
a second partition wall disposed between the upper space of the first crucible and the upper space of the second crucible, wherein
an exhaust passage is disposed between the first partition wall of the first frame and the second partition wall of the second frame, and
the first partition wall of the first frame contacts the second partition wall of the second frame.

2. The deposition source of claim 1, wherein the first nozzle and the second nozzle are arranged in a first direction.

3. The deposition source of claim 2, wherein the exhaust passage extends in the first direction.

4. The deposition source of claim 3, wherein the first crucible and the second crucible are arranged in a second direction intersecting the first direction.

5. The deposition source of claim 4, wherein each of the first crucible and the second crucible extends in the first direction.

6. The deposition source of claim 1, further comprising:
a fastening member penetrating the exhaust passage and fastening the first partition wall and the second partition wall.

7. The deposition source of claim 6, wherein the fastening member is a bolt.

8. The deposition source of claim 1, wherein
a lower portion of the exhaust passage is formed as a portion of the first partition wall, and
an upper portion of the exhaust passage is formed as a portion of the second partition wall.

9. The deposition source of claim 8, wherein
the upper portion of the exhaust passage is formed as a trench of the second partition wall, and
the lower portion of the exhaust passage is formed as a flat surface of the first partition wall.

10. The deposition source of claim 8, wherein
the upper portion of the exhaust passage is formed as a flat surface of the second partition wall, and
the lower portion of the exhaust passage is formed as a trench of the first partition wall.

11. The deposition source of claim 8, wherein
the upper portion of the exhaust passage is formed as a trench of the second partition wall, and
the lower portion of the exhaust passage is formed as a trench of the first partition wall.

12. A deposition source comprising:
a (1-1)th frame including a lower space of a first crucible;
a (1-2)th frame including a lower space of a second crucible; and
a second frame including:
an upper space of the first crucible,
an upper space of the second crucible,
a first nozzle connected to the first crucible, and
a second nozzle connected to the second crucible, wherein
a first portion of a partition wall of the second frame disposed between the first crucible and the second crucible contacts the (1-1)th frame, and
a second portion of the partition wall of the second frame contacts the (1-2)th frame.

13. The deposition source of claim 12, wherein a portion of the (1-1)th frame in contact with the first portion of the partition wall of the second frame is spaced apart from a portion of the (1-2)th frame in contact with the second portion of the partition wall of the second frame.

14. The deposition source of claim 12, wherein the first nozzle and the second nozzle are arranged in a first direction.

15. The deposition source of claim 14, wherein the first crucible and the second crucible are arranged in a second direction intersecting the first direction.

16. The deposition source of claim 15, wherein each of the first crucible and the second crucible extends in the first direction.

17. A deposition source comprising:
a first frame including a lower space of a first crucible and a lower space of a second crucible;
a (2-1)th frame including:
an upper space of the first crucible, and
a first nozzle connected to the first crucible; and
a (2-2)th frame including:
an upper space of the second crucible, and
a second nozzle connected to the second crucible, wherein
a first portion of a partition wall of the first frame disposed between the first crucible and the second crucible contacts the (2-1)th frame, and
a second portion of the partition wall of the first frame contacts the (2-2)th frame.

18. The deposition source of claim 17, wherein a portion of the (2-1)th frame in contact with the first portion of the partition wall of the first frame is spaced apart from a portion of the (2-2)th frame in contact with the second portion of the partition wall of the first frame.

19. The deposition source of claim 17, wherein the first nozzle and the second nozzle are arranged in a first direction.

20. The deposition source of claim 19, wherein the first crucible and the second crucible are arranged in a second direction intersecting the first direction.
